(19) United States
(12) Patent Application Publication
(10) Pub. No.: US 2022/0341033 A1
(43) Pub. Date: Oct. 27, 2022

(54) FILM-FORMING METHOD

(71) Applicant: Tokyo Electron Limited, Tokyo (JP)

(72) Inventors: Shinichi IKE, Nirasaki-shi, Yamanashi (JP); Shuji AZUMO, Nirasaki-shi, Yamanashi (JP); Yumiko KAWANO, Nirasaki-shi, Yamanashi (JP); Tsutomu HIROKI, Nirasaki-shi, Yamanashi (JP)

(21) Appl. No.: 17/762,484

(22) PCT Filed: Sep. 16, 2020
(86) PCT No.: PCT/JP2020/035098

§ 371 Date: Mar. 22, 2022

(30) Foreign Application Priority Data
Sep. 24, 2019 (JP) 2019-173472

(51) Int. Cl. C23C 16/04; C23C 16/06; C23C 16/52

(52) U.S. Cl. CPC C23C 16/04; C23C 16/06; C23C 16/52

(57) ABSTRACT

The film-forming method of forming a target film on a substrate includes preparing the substrate including a first material layer formed on a surface of a first region, and including a second material layer, which is different from the first material, formed on a surface of a second region; controlling the temperature of the substrate to a first temperature; forming the self-assembled film on a surface of the first material layer at the first temperature by supplying a raw-material gas for a self-assembled film; controlling the temperature of the substrate to a second temperature higher than the first temperature; and further forming a self-assembled film at the second temperature on the first material layer on which the self-assembled film has been formed at the first temperature by supplying the raw-material gas for the self-assembled film.

This is a National Phase Application filed under 35 U.S.C. 371 as a national stage of PCT/JP2020/035098, filed Sep. 16, 2020, an application claiming the benefit of Japanese Application No. 2019-173472, filed Sep. 24, 2019, the content of each of which is hereby incorporated by reference in its entirety.

### TECHNICAL FIELD

The present disclosure relates to a film-forming method.

### BACKGROUND

Patent Document 1 discloses a technique of selectively forming a target film in a specific area of a substrate without using a photolithography technique. Specifically, a technique is disclosed in which a self-assembled monolayer (SAM) that inhibits formation of a target film is formed in a partial region of the substrate and the target film is formed in the remaining region of the substrate.

### PRIOR ART DOCUMENTS

### Patent Documents

Patent Document 1: Japanese Laid-Open Patent Publication No. 2007-501902

The present disclosure provides a technique capable of forming a high-density self-assembled monolayer selectively in a desired region.

### SUMMARY

According to an aspect of the present disclosure, a film-forming method for forming a target film on a substrate is provided, wherein the film-forming method includes: a step of preparing the substrate including a layer of a first material formed on a surface of a first region, and including a layer of a second material, which is different from the first material, formed on a surface of a second region; a step of controlling the temperature of the substrate to a first temperature; a step of forming a self-assembled film on a surface of the layer of the first material at the first temperature by supplying a raw-material gas for the self-assembled film; a step of controlling the temperature of the substrate to a second temperature higher than the first temperature; and a step of further forming a self-assembled film at the second temperature on the layer of the first material on which the self-assembled film has been formed at the first temperature by supplying a raw-material gas for the self-assembled film.

According to an aspect, it is possible to form a high-density self-assembled monolayer selectively in a desired region.

### BRIEF DESCRIPTION OF DRAWINGS

FIG. 1 is a flowchart illustrating a film-forming method according to a first embodiment.

FIG. 2A is a cross-sectional view illustrating an example of a state of a substrate in each step illustrated in FIG. 1.

FIG. 2B is a cross-sectional view illustrating an example of a state of a substrate in each step illustrated in FIG. 1.

FIG. 2C is a cross-sectional view illustrating an example of a state of a substrate in each step illustrated in FIG. 1.

FIG. 2D is a cross-sectional view illustrating an example of a state of a substrate in each step illustrated in FIG. 1.

FIG. 2E is a cross-sectional view illustrating an example of a state of a substrate in each step illustrated in FIG. 1.

FIG. 3 is a flowchart illustrating a film-forming method according to a second embodiment.

FIG. 4A is a cross-sectional view illustrating an example of a state of a substrate in each step illustrated in FIG. 3.

FIG. 4B is a cross-sectional view illustrating an example of a state of a substrate in each step illustrated in FIG. 3.

FIG. 4C is a cross-sectional view illustrating an example of a state of a substrate in each step illustrated in FIG. 3.

FIG. 4D is a cross-sectional view illustrating an example of a state of a substrate in each step illustrated in FIG. 3.

FIG. 4E is a cross-sectional view illustrating an example of a state of a substrate in each step illustrated in FIG. 3.

FIG. 4F is a cross-sectional view illustrating an example of a state of a substrate in each step illustrated in FIG. 3.

FIG. 5 is a schematic view illustrating an example of a film-forming system for executing a film-forming method according to an embodiment.

FIG. 6 is a cross-sectional view illustrating an example of a processing apparatus that is capable of being used as a film-forming apparatus and an SAM forming apparatus.

### DETAILED DESCRIPTION

Hereinafter, embodiments for executing the present disclosure will be described with reference to drawings. In the specification and drawings, constituent elements that are substantially the same in configuration will be denoted by the same reference numerals, and redundant descriptions may be omitted. Hereinbelow, a description will be made using a vertical direction or relationship in the drawings, but it does not represent a universal vertical direction or relationship.

### First Embodiment

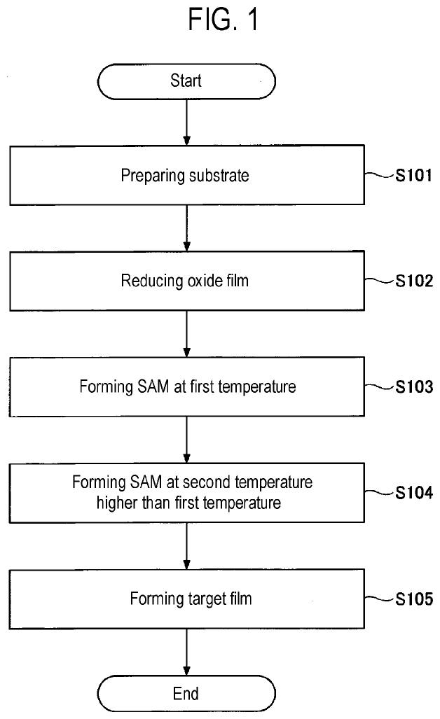

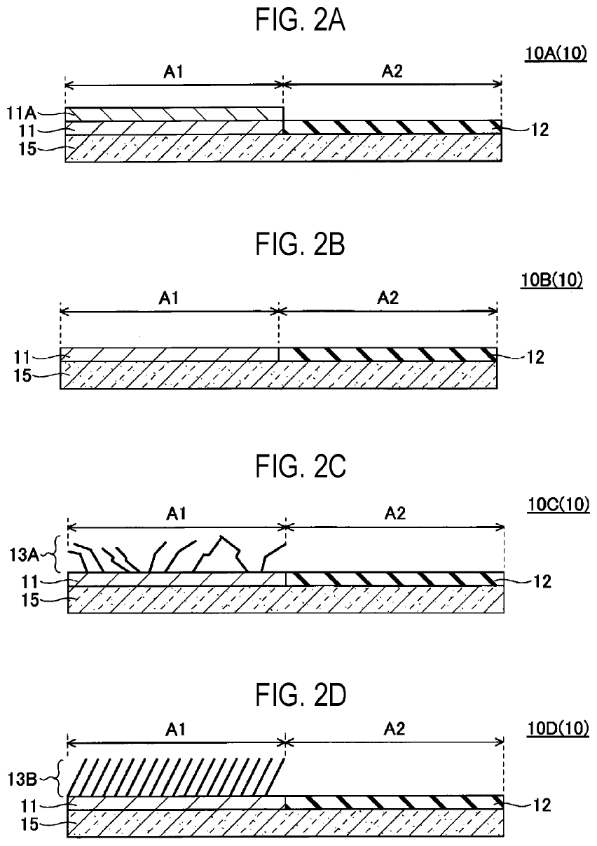

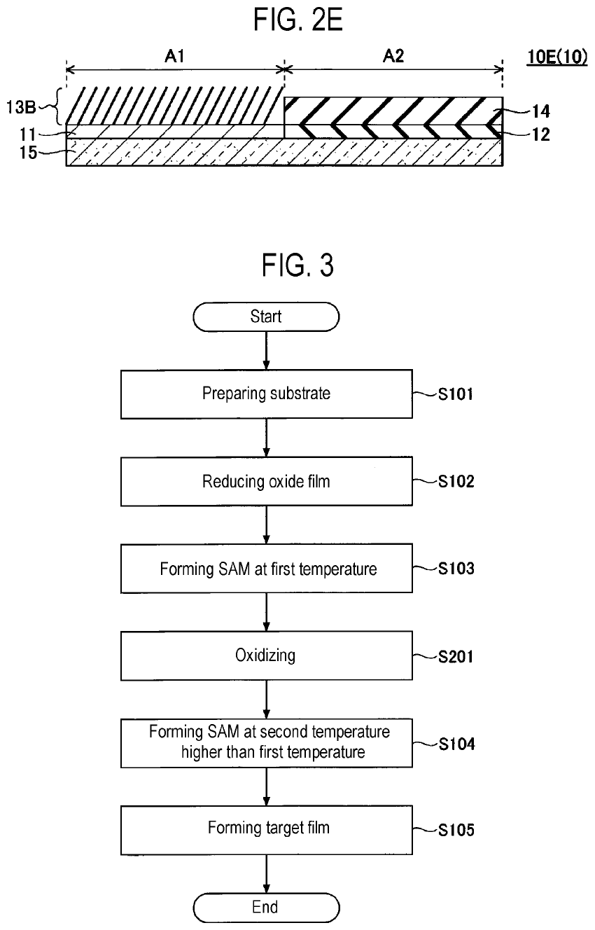

FIG. 1 is a flowchart illustrating a film-forming method according to a first embodiment. FIGS. 2A to 2E are cross-sectional views illustrating examples of a states of a substrate in respective steps illustrated in FIG. 1. FIGS. 2A to 2E illustrate a states of a substrate 10 corresponding to respective steps S101 to S105 illustrated in FIG. 1.

As illustrated in FIG. 2A, a film-forming method includes step S101 of preparing a substrate 10. Preparing the substrate 10 includes, for example, loading the substrate 10 into a processing container (chamber) of, for example, a film-forming apparatus. The substrate 10 includes a conductive film 11, a natural oxide film 11A, an insulating film 12, and a base substrate 15.

The substrate 10 has a first region A1 and a second region A2. Here, as an example, the first region A1 and the second region A2 are adjacent to each other in a plan view. The conductive film 11 is provided on the top surface side of the base substrate 15 in the first region A1, and the insulating film 12 is provided on the top surface side of the base substrate 15 in the second region A2. The natural oxide film 11A is provided on the top surface of the conductive film 11 in the first region A1. In FIG. 2A, the natural oxide film 11A and the insulating film 12 are exposed on the surface of the substrate 10.

The number of first regions A1 is one in FIG. 2A, but may be two or more. For example, two first regions A1 may be arranged with a second region A2 interposed therebetween. Similarly, the number of second regions A2 is one in FIG. 2A, but may be two or more. For example, two second regions A2 may be arranged with a first region A1 interposed therebetween.

In addition, only the first region A1 and the second region A2 are present in FIG. 2A, but a third region may be further present. The third region is a region in which a layer made of a material different from those of the conductive film 11 in the first region A1 and the insulating film 12 in the second region A2 is exposed. The third region may be arranged between the first region A1 and the second region A2, or may be arranged outside the first region A1 and the second region A2.

The conductive film 11 is an example of a layer of the first material. The first material is a metal such as copper (Cu), cobalt (Co), ruthenium (Ru), or tungsten (W). The surface of such a metal is naturally oxidized in the atmosphere over time. The oxide is the natural oxide film 11A. The natural oxide film 11A is removable through a reduction process.

Here, as an example, a mode in which the conductive film 11 is copper (Cu) and the natural oxide film 11A is a copper oxide formed through natural oxidation will be described. The copper oxide as the natural oxide film 11A may include CuO and Cu₂O. For example, a trench (Cu trench) may be formed in the conductive film 11.

The insulating film 12 is an example of a layer of the second material. The second material is, for example, an insulating material containing silicon (Si), and as an example, an insulating film made of a so-called low-k material having a low dielectric constant. Specifically, the insulating film 12 is, for example, silicon oxide, silicon nitride, silicon oxynitride, silicon carbide, silicon oxycarbide, silicon oxycarbonitride, or the like. Hereinafter, silicon oxide is also referred to as SiO regardless of the composition ratio of oxygen and silicon. Similarly, silicon nitride is also referred to as SiN, silicon oxynitride is also referred to as SiON, silicon carbide is also referred to as SiC, silicon oxycarbide is also referred to as SiOC, and silicon oxycarbonitride is also referred to as SiOCN. In the present embodiment, the second material is SiO.

The base substrate 15 is a semiconductor substrate such as a silicon wafer. The substrate 10 may further include, between the base substrate 15 and the conductive film 11, a base film formed of a material different from those of the base substrate 15 and the conductive film 11. Similarly, the substrate 10 may further include, between the base substrate 15 and the insulating film 12, a base film formed of a material different from those of the base substrate 15 and the insulating film 12.

Such a base film may be, for example, a SiN layer or the like. The SiN layer or the like may be, for example, an etching stop layer that stops etching.

The film-forming method includes step S102 of manufacturing the substrate 10 as illustrated in FIG. 2B by reducing the natural oxide film 11A (see FIG. 2A). In order to reduce the natural oxide film 11A, for example, the flow rates of hydrogen (H₂) and argon (Ar) in the processing container of the film-forming apparatus are set to 100 sccm to 2,000 sccm and 500 sccm to 6,000 sccm, respectively, and the pressure in the processing container is set to 1 torr to 100 torr (133.32 Pa to 13,332.2 Pa). In addition, the susceptor is heated such that the temperature of the substrate 10 becomes 150 degrees C to 350 degrees C.

Through step S102, a copper oxide as the natural oxide film 11A is reduced to Cu and removed. As a result, as illustrated in FIG. 2B, a substrate 10 including the conductive film 11, the insulating film 12, and the base substrate 15 is obtained. Cu as the conductive film 11 is exposed on the surface of the first region A1 of the substrate 10.

The reduction process of the natural oxide film 11A is not limited to a dry process, but may be a wet process.

As illustrated in FIGS. 2C and 2D, the film-forming method includes steps S103 and S104 for forming an SAM 13A and an SAM 13B, respectively.

An organic compound for forming the SAM 13A and the SAM 13B may have either a fluorocarbon-based (CFₓ) or alkyl-based (CHₓ) functional group in a case where the organic compound is a thiol-based organic compound, and may be, for example, CF₃(CF₂)[x]CH₂CH₂SH [x=0 to 13], CH₃(CH₂)[ₓ]CH₂SH [x=1 to 14]. In addition, the fluorocarbon-based material (CFₓ) includes fluorobenzenethiol.

Here, when the target film 14 to be described later is formed selectively on the insulating film 12 of the second region A2, the SAM 13B formed through steps S103 and S104 is preferably a high-density SAM in order to completely block the film formation of a target film 14 in the first region A1.

When the substrate temperature at the time of forming the SAM is higher than 150 degrees C, it is possible to form a high-density SAM capable of implementing completely selective film formation of the target film 14. However, when the substrate temperature at the time of forming the SAM is higher than about 200 degrees C, the Cu of the conductive film 11 tends to diffuse. Such a tendency is particularly remarkable when the insulating film 12 made of a low-k material is used. When Cu diffuses into the second region A2, the SAM may be formed in the second region A2 as well. When a Cu trench is present in the conductive film 11, deformation of the Cu trench is observed.

Therefore, in the present embodiment, the step of forming the SAM is divided into two steps, the first step S103 is performed at a relatively low substrate temperature, and in the second step S104, the substrate temperature is made to be higher than that in step S103.

In step S103, the SAM 13A is formed in a state in which the substrate 10 is controlled to a first temperature. In step S104, the SAM 13B is formed in a state in which the substrate 10 is heated to a second temperature higher than the first temperature.

In step S103, the process of forming the SAM 13A is started in a state in which the substrate 10 (see FIG. 2B) is controlled to the first temperature, and the SAM 13A is formed as illustrated in FIG. 2C.

For example, the flow rates of the thiol-based organic compound (raw-material gas) in the gas state and argon (Ar) are set to 50 sccm to 500 sccm and 500 sccm to 6,000 sccm, respectively, the pressure in the processing container of the film-forming apparatus is set to 1 torr to 50 torr (133.32 Pa to 6,666.1 Pa), and the susceptor is heated such that the substrate 10 becomes 100 degrees C (an example of the first temperature). As an example, step S103 can be performed in the same processing container as step S102.

Here, the first temperature at the time of forming the SAM 13A in step S103 may be a temperature at which the movement (diffusion) of Cu of the conductive film 11 does not occur and may be lower than the second temperature in step S104 to be described later. As an example, the first temperature may be a temperature in the range of 50 degrees C to 200 degrees C that satisfies the above-mentioned conditions. Here, as an example, the first temperature is 100 degrees C.

The thiol-based organic compound described above is a compound that easily exchanges electrons with a metal. Accordingly, the SAM has a property of being adsorbed on the surface of the conductive film 11 and being unlikely to be adsorbed on the surface of the insulating film 12 on which the exchange of electrons is unlikely to occur. As a result, when film formation is performed while causing the thiol-based gaseous organic compound to flow in the processing container, the SAM 13A is formed only on the surface of the conductive film 11.

Therefore, through step S103, the SAM 13A is formed on the surface of the conductive film 11. Thus, as illustrated in FIG. 2C, the substrate 10 having the conductive film 11 and the SAM 13A formed in the first region A1 and the insulating film 12 formed in the second region A2 is obtained. In FIG. 2C, the SAM 13A and the insulating film 12 are exposed on the surface of the substrate 10.

The SAM 13A formed in step S103 has a low density of the raw-material gas adsorbed on the surface of the conductive film 11, and, as illustrated in FIG. 2C, molecules of the SAM 13A adsorbed and produced on the surface of Cu of the conductive film 11 are in a state of being oriented in various directions. Here, the SAM 13A is used as a passivation film for preventing the diffusion of Cu in the conductive film 11.

Next, in step S104, the SAM 13B is formed as illustrated in FIG. 2D in a state in which the temperature of the substrate 10 is raised to the second temperature higher than the first temperature. The SAM 13B is formed on the conductive film 11 on which the SAM 13A has been formed.

In order to form the SAM 13B, for example, the flow rates of the thiol-based organic compound in the gas state and argon (Ar) are set to 50 sccm to 500 sccm and 500 sccm to 6,000 sccm, respectively, the pressure in the processing container of the film-forming apparatus is set to 1 torr to 50 torr (133.32 Pa to 6,666.1 Pa), and the susceptor is heated such that the substrate temperature becomes 150 degrees C (an example of the second temperature).

Here, the second temperature of the substrate 10 when forming the SAM 13B in step S104 may be a temperature which is higher than the first temperature which is the substrate temperature at the time of forming the SAM 13A in step S103, and at which decomposition of the SAM does not occur. As an example, the second temperature may be in the range of 100 degrees C to 250 degrees C. Here, as an example, the second temperature is 150 degrees C.

When the processing container includes a high-speed temperature up-and-down stage, step S104 may be performed in the same processing container as step S103.

Since step S104 is performed at a substrate temperature higher than that in step S103, a high-density SAM 13B is obtained. The SAM 13B illustrated in FIG. 2D has a highly oriented molecular layer. Due to a Van der Waals force between the molecules formed at the high density, the molecules of the SAM 13B are in a state of having high orientation and stability.

As described above, through step S104, the SAM 13B is formed on the surface of the conductive film 11, and as illustrated in FIG. 2D, the substrate 10 having the conductive film 11 and the SAM 13B formed in the first region A1 and the insulating film 12 formed in the second region A2 is obtained. In FIG. 2D, the SAM 13B and the insulating film 12 are exposed on the surface of the substrate 10.

In step S104, the SAM 13B is adsorbed only on the surface of the conductive film 11 on which the SAM 13A has been formed, and is not adsorbed on the insulating film 12 of the second region A2. In step S104, the molecules of the newly formed SAM enter the gaps between the molecules of the SAM 13A and are adsorbed on the surface of the conductive film 11. As a result, a high-density SAM 13B is obtained. The SAM 13B has a configuration in which an SAM is further added to the SAM 13A to implement high density. In this way, the SAM 13B can be formed on the surface of the conductive film 11. The SAM 13B inhibits the formation of the target film 14 in the first region A1.

Here, it has been described that in steps S103 and S104, the substrate temperature is controlled to the first temperature and the second temperature to form the SAM 13A and the SAM 13B, respectively. However, step S103 may be divided into a step of controlling (raising) the substrate temperature to the first temperature and a step of forming the SAM 13A after raising the substrate temperature to the first temperature. Similarly, step S104 may be understood by dividing step S104 into a step of controlling (raising) the substrate temperature to the second temperature and a step of forming the SAM 13B after raising the substrate temperature to the second temperature.

As illustrated in FIG. 2E, the film-forming method includes step S105 of forming a target film 14 selectively in the second region A2 using the SAM 13B. The target film 14 is formed of a material different from that of the SAM 13B, for example, a metal, a metal compound, or a semiconductor. Since the SAM 13B inhibits the formation of the target film 14, the target film 14 is formed selectively in the second region A2. When a third region exists in addition to the first region A1 and the second region A2, the target film 14 may or may not be formed in the third region.

The target film 14 is formed through, for example, a chemical vapor deposition (CVD) method or an atomic layer deposition (ALD) method. The target film 14 is formed of, for example, an insulating material. The target film 14, which is an insulating film, can be further laminated on the insulating film 12, which is originally present in the second region A2.

The target film 14 is formed of, for example, an insulating material including silicon. The insulating material containing silicon is, for example, silicon oxide (SiO), silicon nitride (SiN), silicon oxynitride (SiON), or silicon carbide (SiC).

As described above, according to the present embodiment, the natural oxide film 11A, which is present on the surface of the conductive film 11, is reduced, and then the SAM 13A is formed on the surface of the conductive film 11 at the first temperature. The first temperature is a temperature at which diffusion of Cu of the conductive film 11 does not occur, and since the first temperature is a relatively low temperature for forming the SAM, the density of the SAM 13A is not high. The SAM 13A functions as a passivation film for suppressing the diffusion of Cu in the conductive film 11 when the SAM 13B is formed later.

Then, the temperature of the substrate 10 on which the SAM 13A has been formed is raised to the second temperature to form the SAM 13B on the surface of the conductive film 11. The substrate temperature (the second temperature) in step S104 is a temperature at which a high-density SAM can be obtained but decomposition of the SAM does not occur. In step S104, the molecules of the newly formed SAM enter the gaps between the molecules of the SAM 13A as a passivation film and are adsorbed on the surface of the conductive film 11. The SAM 13B is a combination of the SAM 13A formed in step S103 and the SAM newly formed in step S104. In this way, the high-density SAM 13B can be formed selectively in the first region A1 on the surface of the conductive film 11.

Since the high-density SAM 13B can be formed selectively in the first region A1 on the surface of the conductive film 11 as described above, in step S105, the target film 14 is formed selectively in the second region A2 on the surface of the insulating film 12.

In the above description, the mode in which all the processes of steps S101 to S105 are performed in the same processing container has been described. However, all the reduction process in step S102, the process of forming the SAM 13A in step S103, the process of forming the SAM 13B in step S104, and the process of forming the target film 14 in step S105 may be performed in different processing containers of a film-forming apparatus. For example, it is useful when it is desired to independently set processing conditions such as a heating temperature in each step.

In addition, the process of forming the SAM 13A in step S103, the process of forming the SAM 13B in step S104, and the process of forming the target film 14 in step S105 may be performed in the same processing container, and the reduction process in step S102 may be performed in another processing container. For example, it is useful when the reduction process in step S102 is performed by a wet process. In addition, since the substrate temperature differs between step S103 and step S104, the processing container preferably includes a stage in which high-speed temperature up-and-down is possible.

Furthermore, the process of forming the SAM 13A in step S103 and the process of forming the SAM 13B in step S104 may be performed in the same processing container, and the reduction process in step S102 and the process of forming the target film 14 in step S105 may be performed in another processing container. For example, it is useful when the reduction process in step S102 is performed by a wet process, and it is useful when it is desired to perform step S105 in a processing container different from that for forming the SAMs 13A and 13B.

The reduction process in step S102, the process of forming the SAM 13A in step S103, and the process of forming the SAM 13B in step S104 may be performed in the same processing container, and the process of forming the target film 14 in step S105 may be performed in another processing container. For example, it is useful when it is desired to perform step S105 in a processing container different from that for forming the SAMs 13A and 13B.

In addition, the reduction process in step S102 and the process of forming the SAM 13A in step S103 may be performed in the same processing container, and the process of forming the SAM 13B in step S104 and the process of the target film 14 in step S105 may be performed in another processing container. For example, it is useful when the processing container in which step S103 is performed does not include a high-speed temperature up-and-down stage, or when it is desired to perform step S105 in a processing container different from that for forming the SAMs 13A and 13B.

The preparation in step S101 and the reduction process in step S102 are performed in the same processing container.

### Second Embodiment

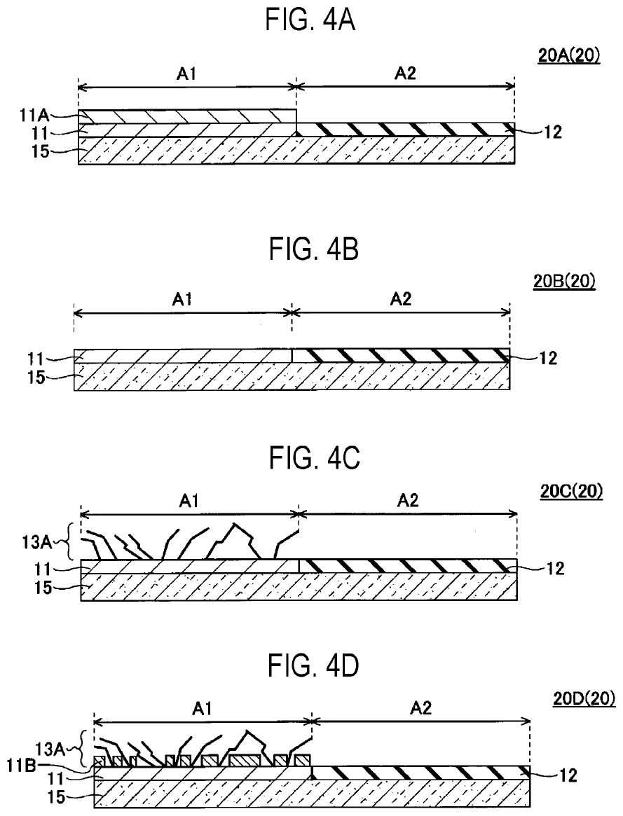

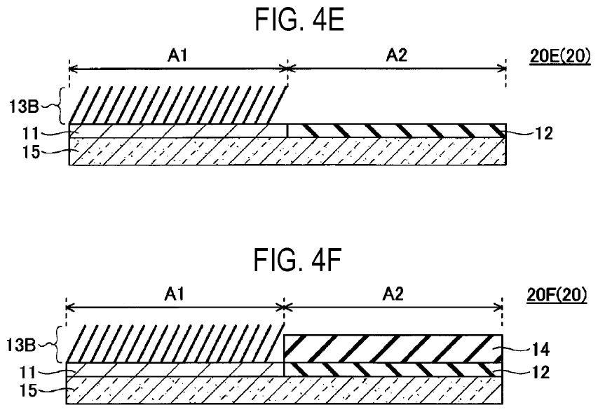

FIG. 3 is a flowchart illustrating a film-forming method according to a second embodiment. FIGS. 4A to 4F are cross-sectional views illustrating examples of a states of a substrate in respective steps illustrated in FIG. 3. FIGS. 4A to 4F illustrate a states of a substrate 20 corresponding to respective steps S101 to S105 illustrated in FIG. 3.

As illustrated in FIG. 3, the film-forming method according to the second embodiment is a film-forming method in which step S201 is inserted between steps S103 and S104 of the film-forming method according to the first embodiment. Therefore, the substrates 20 illustrated in FIGS. 4A to 4C are the same as the substrates 10 illustrated in FIGS. 2A to 2C, respectively. In addition, the substrates 20 illustrated in FIGS. 4E and 4F are the same as the substrates 10 illustrated in FIGS. 2D and 2E, respectively. Therefore, in the following, step S201 in FIG. 3 will be described.

When the substrate 20 illustrated in FIG. 4C is manufactured in step S103, step S201 is performed. The substrate 20 includes an SAM 13A formed on the surface of the conductive film 11 of the first region A1.

The film-forming method includes step S201 of forming a metal oxide film 11B on the surface of the conductive film 11 by oxidizing the surface of the substrate 20, as illustrated in FIG. 4D. In order to form the metal oxide film 11B, for example, the flow rates of oxygen (O₂) as an oxidant and argon (Ar) are set to 500 sccm to 2,000 sccm and 500 sccm to 6,000 sccm, respectively, the pressure in the processing container of the film-forming apparatus is set to 1 torr to 100 torr (133.32 Pa to 13,332.2 Pa), and the substrate 20 is maintained at the same first temperature as in step S103, under an oxygen atmosphere. Here, as an example, the first temperature is 100 degrees C. The oxidant is not limited to oxygen (O₂), and each gas of H₂O, O₃, and H₂O₂ may be used.

As illustrated in FIG. 4D, the metal oxide film 11B is formed on the surface of the conductive film 11 by step S201. The metal oxide film 11B is formed on the surface of Cu in a portion in which the molecules of the SAM 13A are not adsorbed on the Cu of the conductive film 11. Therefore, as illustrated in FIG. 4D, the metal oxide film 11B is formed on the surface of Cu to avoid the SAM 13A. In step S201, a substrate 20 including the conductive film 11, the metal oxide film 11B, the insulating film 12, the SAM 13A, and the base substrate 15 is obtained. In FIG. 4D, the SAM 13A and the insulating film 12 are exposed on the surface of the substrate 20.

The metal oxide film 11B is a copper oxide film formed on the surface of the conductive film 11. The metal oxide film 11B is formed by oxidizing the surface of the conductive film 11 (Cu film). This oxidation process is performed in a state in which the substrate 20 is maintained at a constant temperature in the processing container having an oxygen atmosphere in which the flow rate of oxygen is controlled.

The metal oxide film 11B is formed on the surface of the conductive film 11 while avoiding the molecules of the SAM 13A. The metal oxide film 11B is a copper oxide film having a uniform surface state (distribution state of CuO and Cu₂O), film thickness, and film quality. The copper oxide film as the metal oxide film 11B may contain CuO and Cu₂O. It is considered that, even when CuO and Cu₂O are contained, the distribution of CuO and Cu₂O is uniform throughout the metal oxide film 11B.

When step S201 is completed, the process of forming the SAM 13B at the second temperature by step S104 is performed. Step S104 of the second embodiment is the same process as step S104 of the first embodiment, and the film-forming conditions are the same as the film-forming conditions in step S104 of the first embodiment, but is different from step S104 of the first embodiment in which the metal oxide film 11B is not present and thus no reduction process is involved, in that, in the second embodiment, the SAM 13B is adsorbed on the surface of the conductive film 11 while reducing the metal oxide film 11B.

A thiol-based organic compound is a compound that easily exchanges electrons with a metal and a metal oxide, and in particular, a compound that exchanges electrons more easily with a metal oxide than with a metal. Therefore, the SAM 13B has a property of being adsorbed on the surface of the metal oxide film 11B and not likely to be adsorbed on the surface of the insulating film 12 in which electron exchange is less likely to occur. In addition, the copper oxide as the metal oxide film 11B is a metal oxide that is relatively easy to reduce.

Therefore, when film formation is performed while causing a thiol-based organic compound to flow in the processing container in step S104, the molecules of the SAM enter the portion of the surface of the conductive film 11 in which the molecules of the SAM 13A are not present, to be adsorbed on the surface of the conductive film 11 while the thiol-based organic compound reduces the metal oxide film 11B formed on the surface of the conductive film 11 between the molecules of the SAM 13A. As a result, a high-density SAM 13B is obtained. The SAM 13B is a self-assembled monolayer in which the SAM 13A formed in step S103 and the SAM newly formed in step S104 are combined.

Since the copper oxide as the metal oxide film 11B is reduced by the thiol-based organic compound and removed, the new SAM is adsorbed only on the surface of the conductive film 11 on which the SAM 13A is formed in step S104 and is not adsorbed on the insulating film 12 in the second region A2. As a result, the SAM 13B is formed only on the surface of the conductive film 11.

As described above, by step S104, the metal oxide film 11B is reduced and removed, and the SAM 13B is formed on the surface of the conductive film 11. Thus, as illustrated in FIG. 4E, a substrate 20 having the conductive film 11 and the SAM 13B formed in the first region A1 and the insulating film 12 formed in the second region A2 is obtained. In FIG. 4E, the SAM 13B and the insulating film 12 are exposed on the surface of the substrate 20. In step S104 of the second embodiment, the selectivity and reducibility of the thiol-based organic compound for forming the SAM 13B are used.

When step S104 is completed, the target film 14 is formed selectively on the surface of the insulating film 12 of the second region A2 by step S105.

As described above, according to the present embodiment, the SAM 13B is formed by a two-step film-forming process of step S103 performed at the first temperature and step S104 performed at the second temperature. In addition, between steps S103 and S104, the surface of the conductive film 11 is oxidized in step S201 to form the metal oxide film 11B.

Then, in step S104, by using the metal oxide film 11B having a uniform surface condition, film quality, thickness, and the like, and the selectivity and reducibility of the thiol-based organic compound for manufacturing the SAM 13B, the metal oxide film 11B is reduced and removed, and the SAM 13B is formed on the surface of the conductive film 11. Therefore, the high-density SAM 13B can be formed selectively in the first region A1.

Therefore, according to the present embodiment, it is possible to provide a film-forming method capable of forming a high-density SAM 13B selectively in a desired region.

The copper oxide film as the natural oxide film 11A has a nonuniform surface state, film quality, thickness, and the like, depending on the type or state of chemical mechanical polishing (CMP) performed on the surface of the conductive film 11, and differences in the conditions under which the natural oxide film 11A is naturally oxidized, and the like. Cu is an atom that easily moves in the process of oxidation and reduction.

When an SAM is formed on the surface of the natural oxide film 11A having a nonuniform surface state, film quality, thickness, and the like as described above, it is difficult to form the SAM at high density.

In contrast, in the present embodiment, the copper oxide film as the natural oxide film 11A on the surface of the Cu film as the conductive film 11 is reduced and removed, a passivation film by the SAM 13A is formed on the surface of the conductive film 11, and then, a metal oxide film 11B is formed by uniformly oxidizing the surface of the Cu film. Such a metal oxide film 11B is an oxide film on the conductive film 11 having the surface condition, film quality, thickness, and the like adjusted to be uniform.

When the SAM 13B is formed using such a metal oxide film 11B, the reduction process of the metal oxide film 11B by the SAM 13B is uniformly performed so that a high-density and uniform SAM 13B can be formed.

Therefore, a high-density and uniform SAM 13B can be formed selectively in a desired region (the first region A1).

When forming the SAM 13B on the surface of the conductive film 11 on which the metal oxide film 11B has been formed, since the copper oxide serving as the metal oxide film 11B is reduced and the raw-material gas (a thiol-based organic compound) of the SAM 13B is dehydrated, the reaction is easy to occur so that a relatively high reaction rate can be obtained.

Therefore, according to the film-forming method of the present embodiment, it is possible to improve throughput and to implement a highly productive semiconductor manufacturing process.

Although the mode in which step S201 is performed at the first temperature has been described above, the temperature of the substrate 20 may be raised to the second temperature before performing step S201, and step S201 may be performed at the second temperature. In this case, the process of step S104 may be performed in a state in which the substrate 20 is maintained at the second temperature at the time of completing step S201.

When step S201 is performed at the first temperature, step S103 and step S201 may be performed in the same processing container. When step S201 is performed at the second temperature, step S201 and step S104 may be performed in the same processing container.

In addition, the temperature of the substrate 20 in step S201 may be different from the first temperature and the second temperature. In this case, step S201 may be performed in a processing container different from that for steps S103 and S104, and in the case in which the processing container has a high-speed temperature up-and-down stage, or the like, step S201 may be performed in the same processing container as that for steps S103 and S104.

### Film-Forming System

Next, a system for carrying out a film-forming method according to an embodiment of the present disclosure will be described.

The film-forming method according to an embodiment of the present disclosure may be executed in any of a batch apparatus, a single-wafer apparatus, and a semi-batch apparatus. However, the optimum temperature may differ in each of the above steps, and the execution of each step may be hindered when the surface of a substrate is oxidized and thus the surface state is changed. In view of this point, a multi-chamber-type single-wafer film-forming system, in which each step can be easily set to an optimum temperature and all steps can be performed in a vacuum, is appropriate.

Hereinafter, this multi-chamber-type single-wafer film-forming system will be described.

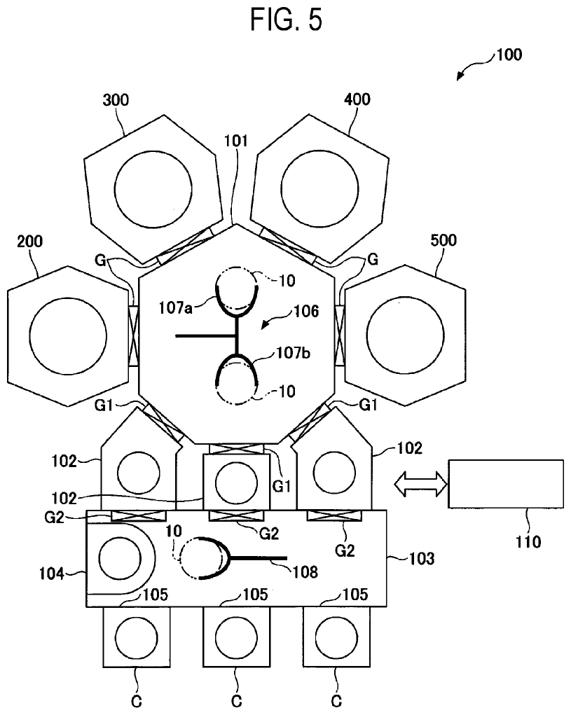

FIG. 5 is a schematic view illustrating an example of a film-forming system for executing a film-forming method according to an embodiment. Here, unless otherwise specified, a case in which a process is performed on a substrate 10 will be described.

As illustrated in FIG. 5, the film-forming system 100 includes an oxidation/reduction processing apparatus 200, an SAM forming apparatus 300, a target film-forming apparatus 400, and a plasma processing apparatus 500. These apparatuses are connected to four walls of a vacuum transport chamber 101 having a heptagonal shape in a plan view via gate valves G, respectively. The interior of the vacuum transport chamber 101 is evacuated by a vacuum pump, and is maintained at a predetermined degree of vacuum. That is, the film-forming system 100 is a multi-chamber-type vacuum-processing system, and is capable of continuously carrying out the above-described film-forming method without breaking the vacuum.

The oxidation/reduction processing apparatus 200 is a processing apparatus that performs a reduction process on a substrate 10 or 20 (see FIGS. 2A and 4A) and an oxidation process for manufacturing a substrate 20 (see FIG. 4D).

The SAM forming apparatus 300 is an apparatus for forming SAMs 13A and 13B selectively by supplying a gas of a thiol-based organic compound for forming the SAMs 13A and 13B in order to form the SAMs 13A and 13B on a substrate 10 (see FIGS. 2C and 2D) and a substrate 20 (see FIGS. 4C and 4E).

The target film-forming apparatus 400 is an apparatus that forms a silicon oxide (SiO) film or the like as a target film 14 on the substrate 10 (see FIG. 2E) and the substrate 20 (see FIG. 4F) through CVD or ALD.

The plasma processing apparatus 500 is configured to perform a process of removing an SAM 13B by etching.

Three load-lock chambers 102 are connected to the other three walls of the vacuum transport chamber 101 via gate valves G1, respectively. An atmospheric transport chamber 103 is provided on the side opposite to the vacuum transport chamber 101, with the load-lock chambers 102 interposed therebetween. The three load-lock chambers 102 are connected to the atmospheric transport chamber 103 via the gate valves G2, respectively. The load-lock chambers 102 perform pressure control between the atmospheric pressure and the vacuum when a substrate 10 is transported between the atmospheric transport chamber 103 and the vacuum transport chamber 101.

The wall of the atmospheric transport chamber 103 opposite to the wall, on which the load-lock chambers 102 are mounted, includes three carrier mounting ports 105 in each of which a carrier (e.g., a FOUP) C for accommodating a substrate 10 is installed. In addition, on a side wall of the atmospheric transport chamber 103, an alignment chamber 104 configured to perform alignment of a substrate 10 is provided. The atmospheric transport chamber 103 is configured to form a downflow of clean air therein.

In the vacuum transport chamber 101, a first transport mechanism 106 is provided. The first transport mechanism 106 transports a substrate 10 to the oxidation/reduction processing apparatus 200, the SAM forming apparatus 300, the target film-forming apparatus 400, the plasma processing apparatus 500, and the load-lock chambers 102. The first transport mechanism 106 has two independently movable transport arms 107a and 107b.

A second transport mechanism 108 is provided in the atmospheric transport chamber 103. The second transport mechanism 108 is configured to transport a substrate 10 to the carriers C, the load-lock chambers 102, and the alignment chamber 104.

The film-forming system 100 has an overall controller 110. The overall controller 110 includes a main controller having a CPU (a computer), an input device (a keyboard, a mouse, or the like), an output device (e.g., a printer), a display device (a display or the like), and a storage device (a storage medium). The main controller controls each component of the oxidation/reduction processing apparatus 200, the SAM forming apparatus 300, the target film-forming apparatus 400, the plasma processing apparatus 500, the vacuum transport chamber 101, and the load-lock chambers 102. The main controller of the overall controller 110 causes the film-forming system 100 to execute operations for carrying out the film-forming methods of the first and second embodiments based on a processing recipe stored in, for example, a storage medium embedded in a storage device or a storage medium set in the storage device. Each apparatus may be provided with a lower-level controller, and the overall controller 110 may be configured as an upper-level controller.

In the film-forming system configured as described above, the second transport mechanism 108 takes out a substrate 10 from a carrier C connected to the atmospheric transport chamber 103, passes through the alignment chamber 104, and then loads the substrate 10 into one of the load-lock chambers 102. Then, after the interior of the load-lock chamber 102 is evacuated, the first transport mechanism 106 transports the substrate 10 to the oxidation/reduction processing apparatus 200, the SAM forming apparatus 300, the target film-forming apparatus 400, and the plasma processing apparatus 500 so as to perform the film-forming processes of the first and second embodiments. Then, if necessary, the plasma processing apparatus 500 removes an SAM 13 or the like through etching.

After the above-described processes are completed, the substrate 10 is transported to one of the load-lock chambers 102 by the first transport mechanism 106, and the substrate 10 in the load-lock chamber 102 is returned to the carrier C by the second transport mechanism 108.

By performing the above-described processes simultaneously in parallel on a plurality of substrates 10, selective film-forming processes on a predetermined number of substrates 10 are completed.

Since each of these processes is performed by an independent single-wafer apparatus, it is easy to set the optimum temperature for each process, and since a series of processes can be performed without breaking vacuum, it is possible to suppress oxidation during the processes.

### Examples of Film-Forming Apparatus and SAM Forming Apparatus

Next, examples of the oxidation/reduction processing apparatus 200, a film-forming apparatus such as the target film-forming apparatus 400, and the SAM forming apparatus 300 will be described.

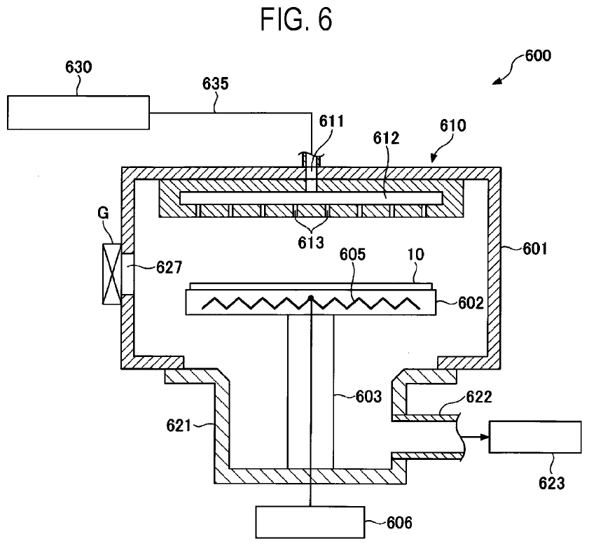

FIG. 6 is a cross-sectional view illustrating an example processing apparatus that can be used as a film-forming apparatus and an SAM forming apparatus.

The oxidation/reduction processing apparatus 200, the film-forming apparatus such as the target film-forming apparatus 400, and the SAM forming apparatus 300 may be configured as apparatuses having similar configurations, and may be configured as, for example, a processing apparatus 600 illustrated in FIG. 6.

The processing apparatus 600 includes a substantially cylindrical processing container (chamber) 601 configured to be hermetically sealed, and a susceptor 602 configured to horizontally support a substrate 10 thereon is disposed in the processing container 601, while being supported by a cylindrical support member 603 provided in the center of the bottom wall of the processing container 601. A heater 605 is embedded in the susceptor 602, and the heater 605 heats the substrate 10 to a predetermined temperature by being fed with power from a heater power supply 606. The susceptor 602 is provided with a plurality of wafer lifting pins (not illustrated) to protrude and retract with respect to the surface of the susceptor 602 so as to support and raise/lower the substrate 10.

A shower head 610 configured to introduce a processing gas for forming a film or an SAM into the processing container 601 in the form of a shower is provided on the ceiling wall of the processing container 601 to face the susceptor 602. The shower head 610 is provided in order to eject a gas supplied from a gas supply mechanism 630, which will be described later, into the processing container 601, and a gas inlet port 611 for gas introduction is formed in the upper portion thereof. A gas diffusion space 612 is formed inside the shower head 610, and a large number of gas ejection holes 613 communicating with the gas diffusion space 612 are formed in the bottom surface of the shower head 610.

The bottom wall of the processing container 601 is provided with an exhaust chamber 621, which protrudes downwards. An exhaust pipe 622 is connected to the side surface of the exhaust chamber 621, and an exhaust apparatus 623 including a vacuum pump, a pressure control valve and the like is connected to the exhaust pipe 622. By operating the exhaust apparatus 623, the interior of the processing container 601 can be brought into a predetermined depressurized (vacuum) state.

A loading/unloading port 627 for loading/unloading a substrate 10 to/from the vacuum transport chamber 101 is provided in the side wall of the processing container 601, and the loading/unloading port 627 is opened and closed by a gate valve G.

The gas supply mechanism 630 includes, for example, supply sources for gases necessary for forming the target film 14 or the SAM 13, an individual pipe for supplying a gas from each supply source, an opening/closing valve provided in the individual pipe, and a flow rate controller such as a mass flow controller that performs flow rate control of a gas, and further includes a gas supply pipe 635 configured to guide a gas from the individual pipe to the shower head 610 through the gas inlet port 611.

When the processing apparatus 600 performs ALD film formation of silicon oxide (SiO) as the target film 14, the gas supply mechanism 630 supplies a raw-material gas of an organic compound and a reaction gas to the shower head 610. In addition, when the processing apparatus 600 forms an SAM, the gas supply mechanism 630 supplies the vapor of a compound for forming the SAM into the processing container 601. The gas supply mechanism 630 is configured to be able to supply an inert gas such as N₂ gas or Ar gas as a purge gas or a heat transfer gas as well.

In the processing apparatus 600 configured as described above, the gate valve G is opened, and a substrate 10 is loaded into the processing container 601 through the loading/unloading port 627, and is placed on the susceptor 602. Since the susceptor 602 is heated to a predetermined temperature by the heater 605, the wafer is heated when the inert gas is introduced into the processing container 601. Then, the interior of the processing container 601 is evacuated by the vacuum pump of the exhaust apparatus 623 such that the pressure inside the processing container 601 is adjusted to a predetermined pressure.

Next, when the processing apparatus 600 performs ALD film formation of silicon oxide (SiO) as the target film 14, supply of the raw-material gas of the organic compound and supply of the reaction gas from the gas supply mechanism 630 are alternately performed, with purging of the interior of the processing container 601 interposed between the supply of the raw-material gas and the supply of the reaction gas. When the processing apparatus 600 forms an SAM, the gas supply mechanism 630 supplies the vapor of the organic compound for forming the SAM into the processing container 601.

Although embodiments of the substrate processing method according to the present disclosure have been described above, the present disclosure is not limited to the above-described embodiments. Various changes, modifications, substitutions, additions, deletions, and combinations can be made within the scope of the claims. Of course, these also fall within the technical scope of the present disclosure.

The present international application claims priority based on Japanese Patent Application No. 2019-173472 filed on Sep. 24, 2019, the disclosure of which is incorporated herein in its entirety by reference.

### EXPLANATION OF REFERENCE NUMERALS

10, 20: substrate, 11: conductive film, 11A: natural oxide film, 11B: metal oxide film, 12: insulating film, 13A, 13B: SAM, 14: target film, 15: base substrate

1. A film-forming method of forming a target film on a substrate, the method comprising:
preparing the substrate including a layer of a first material formed on a surface of a first region, and including a layer of a second material, which is different from the first material, formed on a surface of a second region;
controlling a temperature of the substrate to a first temperature;
forming a self-assembled film on a surface of the layer of the first material at the first temperature by supplying a raw-material gas for the self-assembled film;
controlling the temperature of the substrate to a second temperature higher than the first temperature; and
further forming a self-assembled film at the second temperature on the layer of the first material on which the self-assembled film has been formed at the first temperature by supplying the raw-material gas for the self-assembled film.

2. The film-forming method of claim 1, further comprising:
reducing the surface of the layer of the first material after the preparing the substrate and before the forming the self-assembled film at the first temperature.

3. The film-forming method of claim 2, further comprising:
oxidizing the layer of the first material on which the self-assembled film has been formed at the first temperature, after the forming the self-assembled film at the first temperature, and before raising the temperature of the substrate to the second temperature or after raising the temperature of the substrate to the second temperature before the forming the self-assembled film at the second temperature.

4. The film-forming method of claim 3, wherein the first temperature is a temperature at which diffusion of the first material does not occur.

5. The film-forming method of claim 4, wherein the second temperature is a temperature at which decomposition of the self-assembled film does not occur.

6. The film-forming method of claim 5, wherein the first material is copper, cobalt, ruthenium, or tungsten.

7. The film-forming method of claim 6, wherein the second material is an insulating material including silicon.

8. The film-forming method of claim 7, wherein a material of the self-assembled film is a material of a thiol-based self-assembled film.

9. The film-forming method of claim 8, further comprising:
forming the target film on a surface of the layer of the second material.

10. The film-forming method of claim 1, further comprising:
oxidizing the layer of the first material on which the self-assembled film has been formed at the first temperature, after the forming the self-assembled film at the first temperature, and before raising the temperature of the substrate to the second temperature or after raising the temperature of the substrate to the second temperature before the forming the self-assembled film at the second temperature.

11. The film-forming method of claim 1, wherein the first temperature is a temperature at which diffusion of the first material does not occur.

12. The film-forming method of claim 1, wherein the second temperature is a temperature at which decomposition of the self-assembled film does not occur.

13. The film-forming method of claim 1, wherein the first material is copper, cobalt, ruthenium, or tungsten.

14. The film-forming method of claim 1, wherein the second material is an insulating material including silicon.

15. The film-forming method of claim 1, wherein a material of the self-assembled film is a material of a thiol-based self-assembled film.

16. The film-forming method of claim 1, further comprising:
forming the target film on a surface of the layer of the second material.
